(19) United States
(12) Patent Application Publication
(10) Pub. No.: US 2026/0068751 A1
(43) Pub. Date: Mar. 5, 2026

(54) PACKAGE STRUCTURE

(71) Applicant: Advanced Semiconductor Engineering, Inc., Kaohsiung (TW)

(72) Inventor: Kuofeng HUANG, Kaohsiung (TW)

(73) Assignee: Advanced Semiconductor Engineering, Inc., Kaohsiung (TW)

(21) Appl. No.: 18/817,128

(22) Filed: Aug. 27, 2024

(51) Int. Cl. H01L 25/16; H01L 23/00; H01L 23/31; H01L 23/48; H01L 23/538

(52) U.S. Cl. CPC H01L 25/162; H10D 1/68

(57) ABSTRACT

A package structure is provided. The package structure includes a processing module, a storage module, and a power regulating module. The processing module includes a processing element having a first side configured to receive power. The power regulating module is disposed adjacent to the processing module. The power regulating module includes a first portion and a second portion. The first portion is configured to decouple a first noise from a first power signal and transmit the first power signal to the first side of the processing element. The second portion is configured to transmit a second power signal to the storage module.

### BACKGROUND

### 1. Technical Field

The present disclosure relates generally to a package structure.

### 2. Description of the Related Art

Currently, an electronic component in a package that is designed to receive power and transmit signal through opposite sides may be arranged with a decoupling capacitor. The package may further include a fan-our redistribution layer (RDL) connecting the electronic component to solder balls. However, the power path may be relatively long depending on the arrangement of the decoupling capacitor, which may undesirably reduce the power efficiency and power supply stability. For example, the decoupling capacitor may be mounted outside of the fan-out RDL of the package, the electronic component may have an active surface facing the decoupling capacitor and configured to receive electrical signals, and a power signal may be received by the solder balls and transmitted through the fan-out RDL, bypassing the decoupling capacitor, and then transmitted through the fan-out RDL again and then conductive pillars to the backside of the electronic component.

### SUMMARY

In one or more arrangements, a package structure includes a processing module, a storage module, and a power regulating module. The processing module includes a processing element having a first side configured to receive power. The power regulating module is disposed adjacent to the processing module. The power regulating module includes a first portion and a second portion. The first portion is configured to decouple a first noise from a first power signal and transmit the first power signal to the first side of the processing element. The second portion is configured to transmit a second power signal to the storage module.

In one or more arrangements, a package structure includes a processing module, a storage module, and a power regulating module. The processing module includes a processing element and a decoupling element. The processing element has a first side. The decoupling element is configured to decouple a first noise from a first power signal and transmit the first power signal to the first side of the processing element. The storage module is over the processing module. The power regulating module is disposed adjacent to the processing module and is configured to transmit a first signal to the storage module.

In one or more arrangements, a package structure includes a processing module and a power regulating module. The processing module includes a processing element having a first side configured to receive power. The power regulating module is disposed adjacent to the processing module. The power regulating module is configured to transmit a power signal. A power path is configured to transmit the power signal by vertically passing the power regulating module and horizontally extending toward the first side of the processing element.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 2 is a cross-section of a package structure in accordance with some arrangements of the present disclosure.

FIG. 3 is a cross-section of a package structure in accordance with some arrangements of the present disclosure.

FIG. 4 is a cross-section of a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

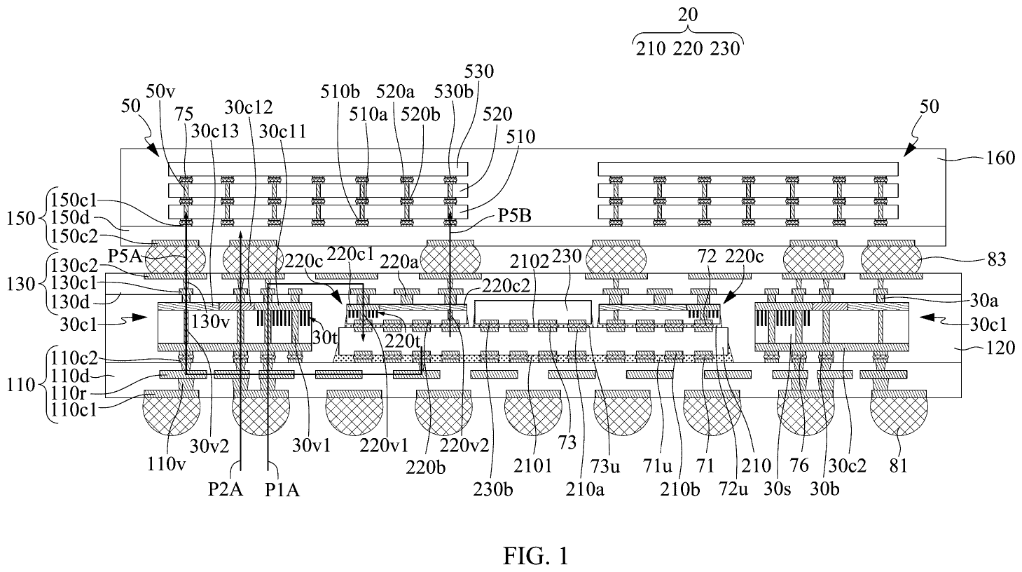

FIG. 1 is a cross-section of a package structure 1 in accordance with some arrangements of the present disclosure. The package structure 1 may include substrates 110, 130, and 150, encapsulants 120 and 160, a processing module 20, power regulating modules 30, storage modules 50, connection elements 71, 72, 73, 75, and 76, and electrical contacts 81 and 83.

The substrate 110 may support and electrically connect to the processing module 20 and the power regulating modules 30. The substrate 110 may include, for example, a printed circuit board, such as a paper-based copper foil laminate, a composite copper foil laminate, or a polymer-impregnated glass-fiber-based copper foil laminate. The substrate 110 may include an interconnection structure, such as a plurality of conductive traces and/or a plurality of conductive vias. In some arrangements, the substrate 110 includes a ceramic material, a metal plate, an organic substrate, or a leadframe. In some arrangements, the substrate 110 may include a coreless substrate. In some arrangements, the substrate 110 may include a two-layer substrate which includes a core layer and a conductive material and/or structure disposed on an upper surface and a bottom surface of the substrate 110. The conductive material and/or structure may include a plurality of conductive traces. In some arrangements, the substrate 110 includes a dielectric layer 110d, a conductive layer 110r (also referred to as “a circuit layer” or “a fan-out redistribution layer (RDL)”), and conductive pads 110c1 and 110c2, and conductive vias 110v electrically connecting the conductive pads 110c1 and 110c2 with the conductive layer 110r. The conductive pads 110c1 and 110c2, the conductive layer 110r, and the conductive vias 110v may include a conductive material such as a metal or metal alloy. Examples include gold (Au), silver (Ag), aluminum (Al), copper (Cu), or an alloy thereof. The substrate 110 may be referred to as a redistribution layer (RDL).

The processing module 20 may be disposed over and electrically connected to the substrate 110. In some arrangements, the processing module 20 includes a processing element 210, one or more decoupling elements 220, and at least one integrated element 230. The decoupling elements 220 and the integrated element 230 may be disposed over the processing element 210. The processing element 210 may have a surface 2101 and a surface 2102 opposite to the surface 2101. The surface 2101 may be an active surface, and the surface 2102 may be a backside surface or a passive surface. In some arrangements, the surface 2102 (also referred to as “a first side”) of the processing module 20 is configured to receive an electrical signal (also referred to as “a first electrical signal”). The surface 2012 may be configured to receive power (e.g., a power signal). In some arrangements, the surface 2101 (or the active surface) of the processing module 20 is configured to receive an electrical signal (also referred to as “a second electrical signal”) different from the electrical signal received by the surface 2102.

In some arrangements, the processing element 210 has a surface (e.g., the surface 2102) configured to receive power (e.g., the power signal). The processing element 210 may be a processing chiplet. In some arrangements, the processing element 210 includes a CPU chiplet, a MCU chiplet, a GPU chiplet, an ASIC chiplet, or the like. In some arrangements, the processing element 210 includes conductive pads 210a and 210b, and the processing element 210 is electrically connected to the substrate 110 through the conductive pads 210b, the connection elements 71, and conductive pads 110c2. A protective element 71u may further encapsulate the conductive pads 210b, the connection elements 71, and conductive pads 110c2. The protective element 71u may be or include an underfill. The underfill may include an epoxy resin having fillers, a molding compound (e.g., an epoxy molding compound or other molding compound), polyimide (PI), a phenolic compound or material, a material with a silicone dispersed therein, or a combination thereof. The connection elements 71 may include conductive bumps, which may be or may include Ag, Al, Cu, another metal, a solder alloy, or a combination thereof.

In some arrangements, the decoupling element 220 is configured to decouple noise from an electrical signal. The decoupling element 220 and the power regulating module 30 may be configured to decouple noises of different frequencies. The decoupling element 220 may be configured to decouple noise from a power signal. In some arrangements, the decoupling element 220 is configured to decouple noise from a power signal and transmit the power signal to the processing element 210. The decoupling element 220 may include decoupling capacitors. The decoupling element 220 may be referred to as a decoupling element. In some arrangements, the decoupling element 220 is or includes a power distribution network (PDN) element. In some arrangements, the decoupling element 220 includes a conductive structure 220c (also referred to as “a circuit layer”), conductive pads 220a and 220b, and conductive vias 220v1 and 220v2. In some arrangements, the conductive structure 220c includes portions 220c1 and 220c2. The portion 220c1 may further include a plurality of capacitor structures 220t (e.g., deep trench capacitors (DTCs). In some arrangements, a distribution of density of the capacitor structures 220t in the portion 220c1 is greater than a distribution of density of the capacitor structures 220t in the portion 220c2. In some arrangements, the portion 220c1 is configured to decouple noise from a power signal and transmit the power signal to the processing element 210. In some arrangements, the conductive via 220v1 is connected to the portion 220c1 and configured to transmit the power signal. In some arrangements, the portion 220c2 is configured to provide electrical communication between the processing element 210 and the storage module 50. In some arrangements, the portion 220c2 is configured to transmit an electrical signal (e.g., a command signal) from the processing element 210 to control the access to the storage module 50. In some arrangements, the conductive via 220v2 is connected to the portion 220c2 and configured to transmit the electrical signal from the processing element 210 to control access to the storage module 50. The portion 220c1 may be referred to as a decoupling portion, and the portion 220c2 may be referred to as a signal transmission portion. In some arrangements, a width of the conductive via 220v1 is greater than a width of the conductive via 220v2. In some arrangements, the decoupling element 220 is electrically connected to the processing element 210 through the conductive pads 220b, the connection elements 72, and conductive pads 210a. The processing element 210 may be configured to access the storage module 50 through the conductive via 220v2 and the portion 220c2. In some arrangements, the processing element 210 is configured to send an electrical signal (e.g., a command signal) through a path P5B passing the conductive via 220v2 and the portion 220c2 to control the access to the storage module 50. A protective element 72u may further encapsulate the conductive pads 220b, the connection elements 72, and conductive pads 210a. The protective element 72u may be or include an underfill. The connection elements 72 may include conductive bumps, which may be or may include Ag, Al, Cu, another metal, a solder alloy, or a combination thereof.

In some arrangements, the integrated element 230 includes a memory unit and an active element. For example, the integrated element 230 includes a cache unit and an analog circuit. The integrated element 230 may be a chiplet. In some arrangements, a wafer node of the processing element 210 is less than a wafer node of the integrated element 230. In some arrangements, the processing element 210 includes a set of transistors, the integrated element 230 includes a set of transistors, and a gate length of each of the set of the transistors of the processing element 210 is less than a gate length of each of the set of transistors of the integrated element 230. In some arrangements, the wafer node of the processing element 210 may be about 2 nm or 3 nm, and the wafer node of the integrated element 230 may be about 7 nm or 9 nm. In some arrangements, a manufacturing process of the processing element 210 is more advanced than a manufacturing process of the integrated element 230. In some arrangements, the processing element 210 and the integrated element 230 are divided from a monolithic processing component (e.g., a CPU component, a MCU component, a GPU component, an ASIC component). In some arrangements, the processing element 210 and the integrated element 230 collectively provide a fully functionality of an independent processing component or a semiconductor chip (e.g., a CPU chip, a MCU chip, a GPU chip, an ASIC chip). In some arrangements, the integrated element 230 includes conductive pads 230b, and the integrated element 230 is electrically connected to the decoupling element 220 through the conductive pads 230b, the connection elements 73, and conductive pads 220a. A protective element 73u may further encapsulate the conductive pads 230b, the connection elements 73, and conductive pads 220a. The protective element 73u may be or include an underfill. The connection elements 73 may include conductive bumps, which may be or may include Ag, Al, Cu, another metal, a solder alloy, or a combination thereof. As used herein, the term “gate length” refers to or is defined by a length of a gate along a direction extending between two source/drain regions. Nanometers (nm) may be the measurement units used to measure the gate length. As used herein, the term “wafer node” refers to a parameter in a specific semiconductor manufacturing process and its design rules. For example, the wafer node used herein may be defined by a minimum gate width of a chip. A smaller wafer node corresponds to a smaller feature size, which in turn corresponds to smaller transistors.

The power regulating module 30 may be disposed adjacent to the processing module 20. In some arrangements, the power regulating module 30 is disposed over and electrically connected to the substrate 110. In some arrangements, the power regulating module 30 is configured to transmit an electrical signal and decouple noise from the electrical signal received by the electrical contacts 81. The power regulating module 30 may be configured to transmit a power signal and decouple noise from the power signal. In some arrangements, the power regulating module 30 is configured to decouple noise from a power signal and transmit the power signal to the processing module 20. In some arrangements, the power regulating module 30 is configured to decouple noise from a power signal and transmit the power signal to the storage module 50. The power regulating module 30 may be referred to as an integrated module including a signal transmission function and a decoupling function.

In some arrangements, the power regulating module 30 includes a first portion (also referred to as “a decoupling portion”) configured to decouple noise from a power signal and transmit the power signal to a backside surface (e.g., the surface 2102) of the processing element 210. In some arrangements, the power regulating module 30 further includes a second portion (also referred to as “a signal transmission portion”) configured to transmit a power signal to the storage module 50. In some arrangements, the first portion is disposed closer to the processing element 210 than the second portion is. In some arrangements, the power regulating module 30 further includes a third portion (also referred to as “a memory access control portion”) configured to provide electrical communication between the processing element 210 and the storage module 50. In some arrangements, the third portion is configured to transmit an electrical signal from the processing element 210 to the storage module 50. In some arrangements, the third portion is configured to transmit an electrical signal from the processing element 210 to control access to the storage module 50. The electrical signal may be a command signal configured to control the access to the storage module 50. In some arrangements, the first portion is disposed closer to the processing element 210 than the third portion is.

In some arrangements, the power regulating module 30 includes a decoupling element and a conductive element (also referred to as “a connection element”). The decoupling element may be configured to decouple noise from the electrical signal (or the power signal). The conductive element may be configured to transmit the electrical signal (or the power signal). The electrical signal may be a power signal transmitted to the processing module 20, a power signal transmitted to the storage module 50, or a combination thereof. The decoupling element may be electrically coupled to the conductive element, so that noise signals may bypass the decoupling element while the power signal keeps passing along the conductive element.

In some arrangements, the power regulating module 30 includes a substrate layer 30s, dielectric layers 30d1 and 30d2 on opposite surfaces of the substrate layer 30s, conductive structures 30c1 and 30c2 (also referred to as “redistribution layers (RDLs)” or “circuit layers”), conductive via 30v1 and 30v2 (also referred to as “conductive vias”), and conductive pads 30a and 30b. In some arrangements, the conductive structures 30c1 and 30c2 are in the dielectric layers 30d1 and 30d2, respectively, and the conductive vias 30v1 and 30v2 penetrate the substrate layer 30s and electrically connect the conductive structures 30c1 and 30c2. In some arrangements, the conductive pads 30a and 30b electrically connect to the conductive structures 30c1 and 30c2, respectively. In some arrangements, the conductive vias 30v1 and 30v2 may be or include the conductive element that is configured to transmit an electrical signal. In some arrangements, the conductive structures 30c1 and 30c2 include the decoupling element that is configured to decouple noise from the electrical signal. In some arrangements, the power regulating module 30 is electrically connected to the substrate 110 through the conductive pads 30b, the connection elements 76, and conductive pads 110c2. The connection elements 76 may include conductive bumps, which may be or may include Ag, Al, Cu, another metal, a solder alloy, or a combination thereof.

In some arrangements, the conductive structure 30c1 includes portions 30c11, 30c12, and 30c13. The portion 30c11 may further include a plurality of capacitor structures 30t (e.g., deep trench capacitors (DTCs). In some arrangements, a distribution of density of the capacitor structures 30t in a region closer to the processing element 210 (e.g., the portion 30c11) is greater than a distribution of density of the capacitor structures 30t in a region distal from the processing element 210 (e.g., the portion 30c12). In some arrangements, a distribution of density of the capacitor structures 30t in a region closer to the processing element 210 (e.g., the portion 30c11) is greater than a distribution of density of the capacitor structures 30t in a region distal from the processing element 210 (e.g., the portion 30c13). The portion 30c11 may be referred to as the first portion or the decoupling portion, the portion 30c12 may be referred to as the second portion or the signal transmission portion, and the portion 30c13 may be referred to as the third portion of the memory access control portion. In some arrangements, the conductive via 30v1 is configured to transmit a power signal to the processing element 210 and/or the storage module 50, and the conductive via 30v2 is electrically connected to the portion 30c13. In some arrangements, a width of the conductive via 30v1 is greater than a width of the conductive via 30v2. In some arrangements, the portion 30c11 is configured to decouple noise from a power signal and transmit the power signal to the processing element 210. In some arrangements, the power signal may be further decoupled by the decoupling element 220 before transmitted to the processing element 210. The portion 30c11 and the decoupling element 220 may decouple noises of different frequencies from the power signal received by the electrical contacts 81 and transmitted to the processing element 210. In some arrangements, the portion 30c12 is configured to transmit a power signal to the storage module 50. In some arrangements, the portion 30c12 is configured to decouple noise from a power signal and transmit the power signal to the storage module 50. The processing element 210 may be configured to access the storage module 50 through the conductive via 30v2 and the portion 30c13. In some arrangements, the processing element 210 is configured to send an electrical signal (e.g., a command signal) through a path P5A passing the substrate 110 (or the fan-out RDL), the conductive via 30v2, and the portion 30c13 to control the access to the storage module 50.

The encapsulant 120 may encapsulate the processing module 20 and the power regulating module 30. In some arrangements, the encapsulant 120 connects the substrates 110 and 130. The encapsulant 120 may be or include an epoxy resin having fillers, a molding compound (e.g., an epoxy molding compound or other molding compound), PI, a phenolic compound or material, a material with a silicone dispersed therein, or a combination thereof.

The substrate 130 may be over the electrically connected to the processing module 20 and the power regulating module 30. In some arrangements, the substrate 130 includes a dielectric layer 130d, conductive pads 130c1 and 130c2, one or more conductive layers (or circuit layers or RDLs) and conductive vias 130v electrically connecting the conductive pads 130c1 and 130c2 with the conductive layers and the conductive vias. In some arrangements, the conductive pads 130c2 electrically connect to the conductive pads 220a and 30a. The conductive pads 130c1 and 130c2, the conductive layers, and the conductive vias may include a conductive material such as a metal or metal alloy. Examples include Au, Ag, Al, Cu, or an alloy thereof. The substrate 130 may be referred to as a RDL.

The substrate 150 may be over the electrically connected to the substrate 130. In some arrangements, the substrate 150 includes a dielectric layer 150d, conductive pads 150c1 and 150c2, one or more conductive layers (or circuit layers or RDLs) and conductive vias (not shown) electrically connecting the conductive pads 150c1 and 150c2 with the conductive layers and the conductive vias. In some arrangements, the substrate 150 is electrically connected to the substrate 130 through the conductive pads 150c1, the electrical contacts 83, and conductive pads 130c2. The conductive pads 150c1 and 150c2, the conductive layers, and the conductive vias may include a conductive material such as a metal or metal alloy. Examples include Au, Ag, Al, Cu, or an alloy thereof. The substrate 130 may be referred to as a RDL. The electrical contacts 83 may include solder balls or solder bumps.

The storage module 50 may be disposed over the processing module 20. In some arrangements, the storage module 50 is disposed over and electrically connected to the substrate 150. In some arrangements, the storage module 50 includes a plurality of memory dies and a logic die (e.g., dies 510, 520, and 530) stacked over and electrically connected to each other through the connection elements 75. One or more of the dies may include conductive vias 50v electrically connected to the connection element 75. The conductive vias 50v may penetrate opposite surfaces of the die. In some arrangements, conductive pads 530b of the die 530 electrically connect to conductive pads 520a of the die 520 through the connection elements 75. In some arrangements, conductive pads 520b of the die 520 electrically connect to conductive pads 510a of the die 310 through the connection elements 75. The connection elements 75 may include conductive bumps, which may be or may include Ag, Al, Cu, another metal, a solder alloy, or a combination thereof. In some arrangements, conductive pads 510b of the die 510 electrically connect to the conductive pads 150c1 of the substrate 150 through the connection elements 75. The dies may include memory components or memory elements (e.g., the dies 520 and 530) and optionally a logic die (e.g., the die 510). The logic die may be configured to generate a control signal in response to the command signal sent by the processing element 210 to access the memory dies. The storage module 50 may be or include a high bandwidth memory (HBM).

The encapsulant 160 may be disposed over the substrate 150 and encapsulate the storage modules 50. The encapsulant 160 may be or include an epoxy resin having fillers, a molding compound (e.g., an epoxy molding compound or other molding compound), PI, a phenolic compound or material, a material with a silicone dispersed therein, or a combination thereof.

The electrical contacts 81 may be disposed under the substrate 110. In some arrangements, the electrical contacts 81 are electrically connected to the substrate 110. The electrical contacts 81 may include solder balls. The electrical contacts 81 may be or include controlled collapse chip connection (C4) bumps, a ball grid array (BGA), or a land grid array (LGA).

The package structure 1 may include a path P1A configured to provide an electrical signal to the processing module 20 and a path P2A configured to provide an electrical signal to the storage module 50. In some arrangements, the path P1A is configured to decouple noise from the electrical signal and transmit the electrical signal to the processing module 20, and the path P2A is configured to decouple noise from the electrical signal and transmit the electrical signal to the storage module 50. In some arrangements, the path P1A is configured to provide power (e.g., a power signal) to the processing module 20, and the path P2A is configured to provide power (e.g., a power signal) to the storage module 50.

In some arrangements, the path P1A is configured to transmit a power signal to the processing module 20. The path P1A may pass the portion 30c11 of the conductive structure 30c1 of the power regulating module 30 and configured to transmit the power signal. In some arrangements, the path P1A includes a vertical segment configured to transmit the power signal toward the power regulating module 30. In some arrangements, the path P1A vertically passes the power regulating module 30 and then horizontally extends toward the surface 2102 (or the backside) of the processing module 20. As an initial power signal passes the power regulating module 30, some noise signals bypass the decoupling element of the power regulating module 30 while the power signal keeps passing along the path P1A and transmitting by the conductive element of the power regulating module 30, such that these noise signals are decoupled from the transmitted power signal. The power signal, after noise signals decoupled by the power regulating module 30, may be then transmitted along the path P1A horizontally by the conductive layer (not shown) of the substrate 130 toward the surface 2102 (or the backside) of the processing module 20.

In some arrangements, the path P1A may further include another vertical segment configured to transmit the power signal passing the decoupling element 220 and toward the processing element 210. Noise signals (e.g., noise signals of frequencies different from those bypass the power regulating module 30) may bypass the decoupling capacitors of the decoupling element 220, which allows these noise signals to be further decoupled from the transmitted power signal that is transmitted to the processing element 210.

In some arrangements, the path P2A is configured to transmit a power signal to the storage module 50. The path P2A may pass the portion 30c12 of the conductive structure 30c1 of the power regulating module 30 and configured to transmit the power signal. In some arrangements, the path P2A includes a vertical segment configured to transmit the power signal toward the power regulating module 30. In some arrangements, the path P2A vertically passes the power regulating module 30 and is configured to transmit the power signal to the storage module 50. As an initial power signal passes the power regulating module 30, some noise signals bypass the decoupling element (e.g., the portion 30c12) of the power regulating module 30 while the power signal keeps passing along the path P2A and transmitting by the conductive element (e.g., the conductive via 30v1) of the power regulating module 30, such that these noise signals are decoupled from the transmitted power signal. The power signal, after noise signals decoupled by the power regulating module 30, may be then transmitted along the path P2A vertically by the electrical contact 83 toward the storage module 50. In some arrangements, the path P2A further passes a portion of the substrate 130 and a portion of the substrate 150.

Currently, a package structure may include a lower substrate (or a lower fan-out RDL), a processing component disposed over the lower substrate with an active surface facing the lower substrate, a decoupling capacitor disposed under the lower substrate for decoupling noise from a power signal that is transmitted to the processing component, an upper substrate (or an upper fan-out RDL) over the backside surface of the processing component, and a conductive pillar adjacent to the processing component and electrically connecting the lower substrate to the upper substrate. The power signal is transmitted along a path that passes a portion of the lower substrate for the noise to bypass the decoupling capacitor, the conductive pillar to transmit the decoupled power signal to the upper substrate, and then a portion of the upper substrate to reach the backside surface of the processing component. With such design, the power path is relatively long, and thus the power loss is relatively high.

According to some arrangements of the present disclosure, the processing module 20 and the power regulating module 30, which is configured to transmit and decouple a power signal transmitted to the processing module 20, are both disposed over the substrate 110 and encapsulated by the encapsulant 120. The power path (e.g., the paths P1A, P1B, P1C, P1D, and P1E) does not pass the substrate 110, and the path vertically passes along a lateral side of the processing module 20 to provide the decoupled power signal to the backside (e.g., the surface 2102) of the processing module 20. Therefore, the power path is relatively short, such that the power loss or the power consumption is relatively low, and thus the power efficiency is improved.

In addition, according to some arrangements of the present disclosure, the power regulating module 30 is disposed relatively close to the processing module 20 or the processing element 210. Therefore, the path length or the wiring length between the decoupling element and the processing element 210 is relatively short, the resistance can be reduced, the power loss by transmission can be reduced, and the number or the amount of the decoupling capacitors of the decoupling element in the power regulating module 30 can be reduced, which in turns reduces the size of the power regulating module 30 and increases the stability of power supply (particularly for high power).

Furthermore, according to some arrangements of the present disclosure, the power regulating module 30 integrates the decoupling element for decoupling the power signal and the conductive element for transmitting the power signal. As such, the size of the power regulating module 30 is relatively small compared to a total size of a decoupling capacitor and a conductive pillar that are separately disposed in a package structure. Therefore, the size of the package structure 1 is further reduced.

Moreover, according to some arrangements of the present disclosure, the processing element 210 and the integrated element 230 having different nodes. As such, the integrated element 230 can be manufactured by a manufacturing process less advanced than that of the processing element 210, and thus the processing element 210 and the integrated element 230 can be manufactured separately and then assembled into the processing module 20. Therefore, the flexibility of the manufacturing process of the processing module 20 and the package structure 1 is increased, and the yield can be increased as well.

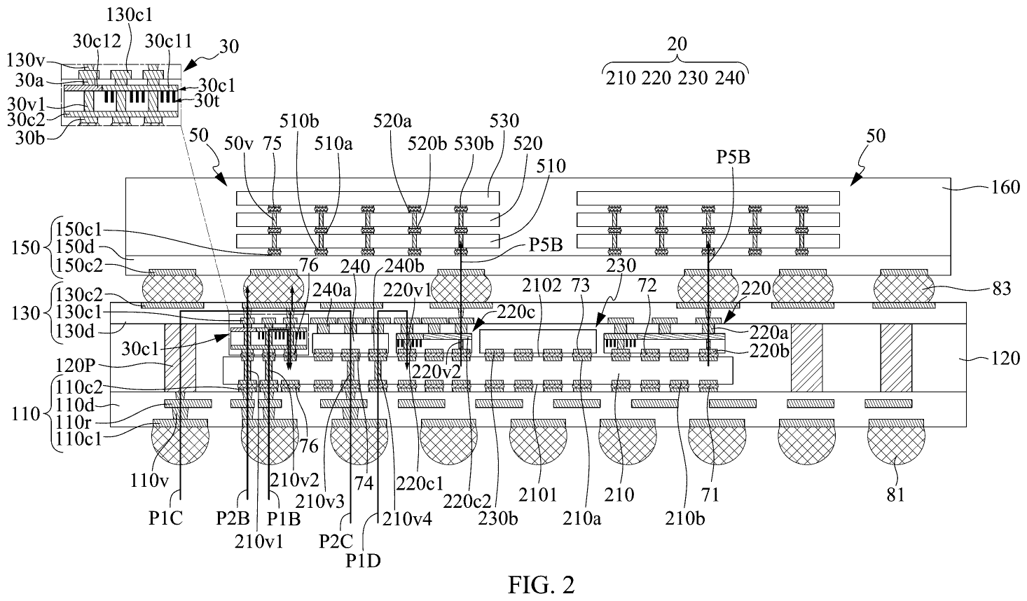

FIG. 2 is a cross-section of a package structure 2 in accordance with some arrangements of the present disclosure. The package structure 2 is similar to the package structure 1 in FIG. 1, and the differences therebetween are described as follows.

The package structure 2 may further include connection elements 74 and conductive pillars 120P.

In some arrangements, the processing module 20 further includes a power management element 240. In some arrangements, the decoupling element 220, the integrated element 230, and the power management element 240 are stacked over and electrically connected to the processing element 210. In some arrangements, the decoupling element 220, the integrated element 230, and the power management element 240 are stacked over and electrically connected to the surface 2102 (or the backside) of the processing element 210.

In some arrangements, the processing element 210 includes conductive via 210v1, 210v2, 210v3, and 210v4. In some arrangements, the conductive vias 210v1 and 210v2 are configured to transmit one or more electrical signals (e.g., power signals) to the power regulating module 30. In some arrangements, the conductive vias 210v3 and 210v4 are configured to transmit one or more electrical signals (e.g., power signals) to the power management element 240.

In some arrangements, the power management element 240 is configured to manage power signals to be supplied or transmitted to the processing module 20 and the storage modules 50. The power management element 240 may be or include a power management IC (PMIC). In some arrangements, the power management element 240 includes conductive pads 240a and 240b. In some arrangements, the power management element 240 is electrically connected to the processing element 210 through the conductive pads 240b, the connection elements 74, and conductive pads 210a, and the power management element 240 is electrically connected to the substrate 130 through the conductive pads 240a and conductive pads 130b. The connection elements 74 may include conductive bumps, which may be or may include Ag, Al, Cu, another metal, a solder alloy, or a combination thereof.

In some arrangements, the power regulating module 30 is stacked over and electrically connected to the processing element 210. In some arrangements, the power regulating module 30 is stacked over and electrically connected to the surface 2102 (or the backside) of the processing element 210. In some arrangements, the power regulating module 30 is closer to the surface 2102 (or the backside) than to the surface 2101 (or the active surface) of the processing module 20. In some arrangements, the power regulating module 30 is electrically connected to the processing element 210 through the conductive pads 30b, the connection elements 76, and conductive pads 210a.

In some arrangements, the storage module 50 is disposed over the processing module 20, and the power regulating module 30 is between the storage module 50 and the processing element 210.

In some arrangements, the conductive pillars 120P are encapsulated by the encapsulant 120. In some arrangements, the substrate 110 is electrically connected to the substrate 130 through the conductive pillars 120P. The conductive pillars 120P may include a conductive material such as a metal or metal alloy. Examples include Au, Ag, Al, Cu, or an alloy thereof.

The package structure 2 may include paths P1B, P1C, and P1D configured to provide electrical signals to the processing module 20 and paths P2B and P2C configured to provide electrical signals to the storage module 50. In some arrangements, the paths P1B, P1C, and P1D are configured to decouple noise from the electrical signals and transmit the electrical signals to the processing module 20, and the paths P2B and P2C are configured to decouple noise from the electrical signals and transmit the electrical signals to the storage module 50. In some arrangements, the paths P1B, P1C, and P1D are configured to provide power (e.g., power signals) to the processing module 20, and the paths P2B and P2C are configured to provide power (e.g., power signals) to the storage module 50.

In some arrangements, the path P1B is configured to transmit a power signal to the processing module 20. The path P1B may pass the power regulating module 30 and configured to transmit the power signal. In some arrangements, the path P1B includes a vertical segment configured to transmit the power signal toward the power regulating module 30. In some arrangements, the path P1B vertically passes the conductive via 210v2 of the processing element 210 of the processing module 20 and the conductive via 30v1 of the power regulating module 30. As an initial power signal passes the conductive via 210v2 of the processing element 210 and then the portion 30c11 of the conductive structure 30c of the power regulating module 30, some noise signals bypass the decoupling element of the power regulating module 30 while the power signal keeps passing along the path P1B and transmitting by the conductive element of the power regulating module 30, such that these noise signals are decoupled from the transmitted power signal. The power signal, after noise signals decoupled by the power regulating module 30, may be then transmitted along the path P1B vertically by the conductive via 30v1 of the power regulating module 30 toward the surface 2102 (or the backside) of the processing element 210 of the processing module 20.

In some arrangements, the path P1C is configured to transmit a power signal to the processing module 20. The path P1C may electrically couple to the power regulating module 30 and configured to transmit the power signal. In some arrangements, the path P1C includes a vertical segment configured to transmit the power signal passing the conductive pillar 120P. In some arrangements, the path P1C vertically passes the conductive pillar 120P. As an initial power signal passes the conductive pillar 120P and then the substrate 130 that electrically couples to the power regulating module 30, some noise signals bypass the decoupling element (e.g., the portion 30c11) of the power regulating module 30 while the power signal keeps passing along the path P1C and transmitting by the conductive element of the power regulating module 30, such that these noise signals are decoupled from the transmitted power signal. The power signal, after noise signals decoupled by the power regulating module 30, may be then transmitted along the path P1C vertically by the conductive via 30v1 of the power regulating module 30 toward the surface 2102 (or the backside) of the processing element 210 of the processing module 20. In some arrangements, the conductive pillar 120P is encapsulated by the encapsulant 120 and configured to transmit the power signal along the path P1C passing the power regulating module 30 to the surface 2102 of the processing element 210.

In some arrangements, the path P1D is configured to transmit a power signal to the processing module 20. The path P1D may pass the conductive via 210v4 of the processing element 210, the power management element 240, and the decoupling element 220 and be configured to transmit the power signal. In some arrangements, the path P1D includes a vertical segment configured to transmit the power signal toward the power management element 240. As an initial power signal passes the conductive via 210v4 and then is transmitted to the power management element 240, the initial power signal may be processed by the power management element 240, e.g., selecting the power signal from the supplied power signals, adjusting the voltage of the power signal, stabilizing the power signal, or other power managing functions. The power signal transmitted from the power management element 240 is then transmitted to the portion 220c1 of the conductive structure 220c of the decoupling element 220, some noise signals bypass the decoupling element of the decoupling element 220 while the power signal keeps passing along the path P1D, such that these noise signals are decoupled from the transmitted power signal. The power signal, after noise signals decoupled by the decoupling element 220, may be then transmitted along the path P1D vertically toward the surface 2102 (or the backside) of the processing element 210 of the processing module 20.

In some arrangements, the path P2B is configured to transmit a power signal to the storage module 50. The path P2B may pass the conductive via 210v1 of processing element 210 and the power regulating module 30 and configured to transmit the power signal. In some arrangements, the path P2B includes a vertical segment configured to transmit the power signal toward the power regulating module 30. In some arrangements, the path P2B vertically passes the conductive via 210v1 and the power regulating module 30 and is configured to transmit the power signal to the storage module 50. As an initial power signal passes the power regulating module 30, some noise signals bypass the decoupling element of the power regulating module 30 while the power signal keeps passing along the path P2B and transmitting by the conductive element of the power regulating module 30, such that these noise signals are decoupled from the transmitted power signal. The power signal, after noise signals decoupled by the power regulating module 30, may be then transmitted along the path P2B vertically by the electrical contact 83 toward the storage module 50.

In some arrangements, the path P2C is configured to transmit a power signal to the storage module 50. The path P2C may pass the conductive via 210v3 of the processing element 210 and the power management element 240, electrically couple to the power regulating module 30, and be configured to transmit the power signal to the storage module 50. As an initial power signal passes the conductive via 210v3 and then is transmitted to the power management element 240, the initial power signal may be processed by the power management element 240, e.g., selecting the power signal from the supplied power signals, adjusting the voltage of the power signal, stabilizing the power signal, or other power managing functions. The power signal transmitted from the power management element 240 is then transmitted to a portion of the substrate 130 that electrically couples to the power regulating module 30, some noise signals bypass the decoupling element of the power regulating module 30 while the power signal keeps passing along the path P2C and transmitting by a portion of the substrate 130 horizontally, such that these noise signals are decoupled from the transmitted power signal. The power signal, after noise signals decoupled by the power regulating module 30, may be then transmitted along the path P2C toward the storage module 50.

According to some arrangements of the present disclosure, the power regulating module 30 is disposed over the processing element 210, the power signal decoupled by the power regulating module 30 can be transmitted directly to the processing element 210 by the path (e.g., the paths P1B and P1C) without passing any horizontal path, and thus the power path can be further reduced. Therefore, the power loss or the power consumption is further reduced, and thus the power efficiency is improved significantly.

In addition, according to some arrangements of the present disclosure, the power path may pass the conductive pillar 120P for transmitting a power signal with a relatively high power for increasing the transmission speed and then pass the power regulating module 30 to decouple noise from the high power signal. Therefore, the power path is relatively short, which is advantageous to increasing the power efficiency, and the power distribution is also improved.

Furthermore, according to some arrangements of the present disclosure, the decoupling element 220 that serves to decouple noise from the power signal transmitted to the processing module 20 is stacked over the electrically connected to the processing element 210 through the connection elements 72. Therefore, the path length or the wiring length between the decoupling capacitors in the decoupling element 220 and the processing element 210 is relatively short, such that there is nearly no voltage drop or only a very small voltage drop of the power signal transmitted between the decoupling element 220 and the processing element 210. Therefore, the power loss by transmission can be reduced, and the number or the amount of the decoupling capacitors in the decoupling element 220 can be reduced, which in turns reduces the size of the decoupling element 220 and increases the stability of power supply (particularly for high power).

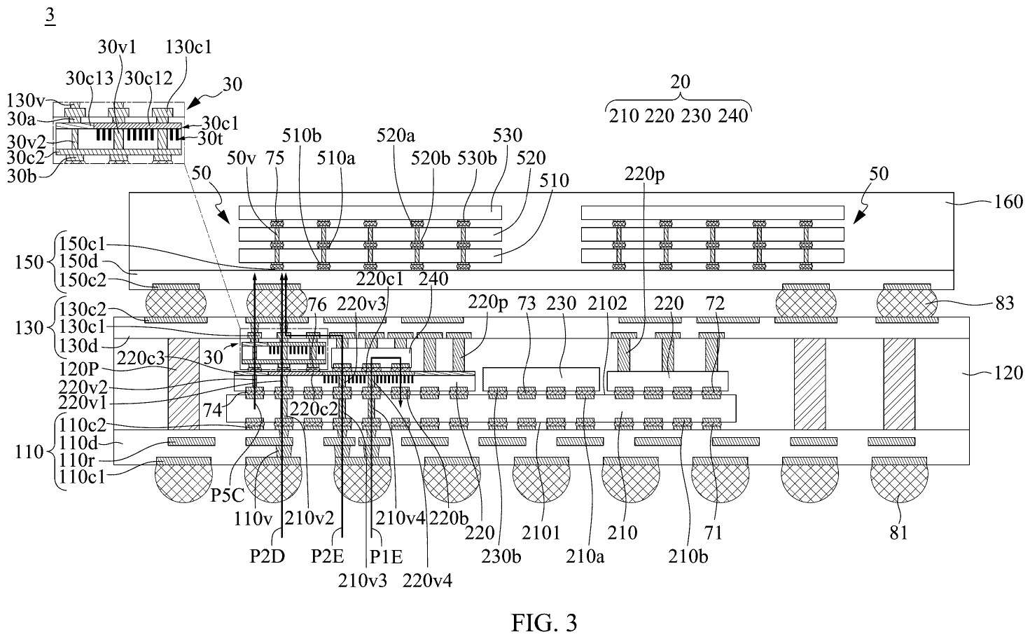

FIG. 3 is a cross-section of a package structure 3 in accordance with some arrangements of the present disclosure. The package structure 3 is similar to the package structure 1 in FIG. 1, and the differences therebetween are described as follows.

In some arrangements, the decoupling element 220 includes conductive via 220v2, 220v3, and 220v4. In some arrangements, the conductive via 220v1 is configured to transmit an electrical signal (e.g., a power signal) to the power regulating module 30. In some arrangements, the conductive via 220v2 is configured to transmit an electrical signal (e.g., a command signal) from the processing element 210 to control the access to the storage module 50. In some arrangements, the processing element 210 is configured to send an electrical signal (e.g., a command signal) through a path P5C passing the conductive via 220v2, the conductive via 30v2, and the portion 30c13 to control the access to the storage module 50. In some arrangements, the conductive vias 220v3 and 220v4 are configured to transmit one or more electrical signals (e.g., power signals) to the power management element 240.

In some arrangements, the decoupling element 220 is configured to decouple noise from an electrical signal (e.g., a power signal) and stacked between the processing element 210 and the power management element 240. In some arrangements, the decoupling element 220 further includes conductive pillars 220p electrically connected to the conductive pads 130c1 of the substrate 130 for transmitting an electrical signal to the substrate 130. In some arrangements, the power management element 240 and the power regulating module 30 are stacked over and electrically connected to the decoupling element 220.

The package structure 3 may include a path P1E configured to provide an electrical signal to the processing module 20 and paths P2D and P2E configured to provide electrical signals to the storage module 50. In some arrangements, the path P1E is configured to decouple noise from the electrical signal and transmit the electrical signal to the processing module 20, and the paths P2D and P2E are configured to decouple noise from the electrical signals and transmit the electrical signals to the storage module 50. In some arrangements, the path P1E is configured to provide power (e.g., power signals) to the processing module 20, and the paths P2D and P2E are configured to provide power (e.g., power signals) to the storage module 50.

In some arrangements, the path P1E is configured to transmit a power signal to the processing module 20. The path P1E may pass the conductive via 220v4 of the decoupling element 220, the conductive via 210v4 of the processing element 210, the power management element 240, and then the decoupling element 220 and be configured to transmit the power signal. In some arrangements, the path P1E includes a vertical segment configured to transmit the power signal toward the power management element 240. As an initial power signal passes the conductive via 210v4 and the conductive via 220v4 to be transmitted to the power management element 240, the initial power signal may be processed by the power management element 240, e.g., selecting the power signal from the supplied power signals, adjusting the voltage of the power signal, stabilizing the power signal, or other power managing functions. The power signal transmitted from the power management element 240 is then transmitted to the decoupling element 220, some noise signals bypass the decoupling element of the decoupling element 220 while the power signal keeps passing along the path P1E, such that these noise signals are decoupled from the transmitted power signal. The power signal, after noise signals decoupled by the decoupling element 220, may be then transmitted along the path P1E vertically toward the surface 2102 (or the backside) of the processing element 210 of the processing module 20.

In some arrangements, the path P2D is configured to transmit a power signal to the storage module 50. The path P2D may pass the conductive via 210v2 of processing element 210, the conductive via 2240v2 of the decoupling element 220, and the power regulating module 30 and configured to transmit the power signal. In some arrangements, the path P2D includes a vertical segment configured to transmit the power signal toward the power regulating module 30. In some arrangements, the path P2D vertically passes the conductive via 210v2, the conductive via 220v2, and the portion 30c12 of the conductive structure 30c1 of the power regulating module 30 and is configured to transmit the power signal to the storage module 50. As an initial power signal passes the power regulating module 30, some noise signals bypass the decoupling element of the power regulating module 30 while the power signal keeps passing along the path P2D and transmitting by the conductive element of the power regulating module 30, such that these noise signals are decoupled from the transmitted power signal. The power signal, after noise signals decoupled by the power regulating module 30, may be then transmitted along the path P2D vertically by the electrical contact 83 toward the storage module 50.

In some arrangements, the path P2E is configured to transmit a power signal to the storage module 50. The path P2E may pass the conductive via 210v3 of the processing element 210, the conductive via 220v3 of the decoupling element 220, and the power management element 240, electrically couple to the power regulating module 30, and be configured to transmit the power signal to the storage module 50. As an initial power signal passes the conductive via 210v3, the conductive via 220v3, and then is transmitted to the power management element 240, the initial power signal may be processed by the power management element 240, e.g., selecting the power signal from the supplied power signals, adjusting the voltage of the power signal, stabilizing the power signal, or other power managing functions. The power signal transmitted from the power management element 240 is then transmitted to a portion of the substrate 130 that electrically couples to the power regulating module 30, some noise signals bypass the decoupling element (e.g., the portion 30c12 of the conductive structure 30c1) of the power regulating module 30 while the power signal keeps passing along the path P2E and transmitting by a portion of the substrate 130 horizontally, such that these noise signals are decoupled from the transmitted power signal. The power signal, after noise signals decoupled by the power regulating module 30, may be then transmitted along the path P2E toward the storage module 50.

According to some arrangements of the present disclosure, the power management element 240 is stacked over the electrically connected to the decoupling element 220 through the connection elements 74. Therefore, the path length or the wiring length between the power management element 240 and the decoupling element 220 is further reduced, such that there is nearly no voltage drop or only a very small voltage drop of the power signal transmitted between the power management element 240 and the decoupling element 220. Therefore, the power loss by transmission can be reduced, and the number or the amount of the decoupling capacitors in the decoupling element 220 can be reduced, which in turns reduces the size of the decoupling element 220 and increases the stability of power supply (particularly for high power).

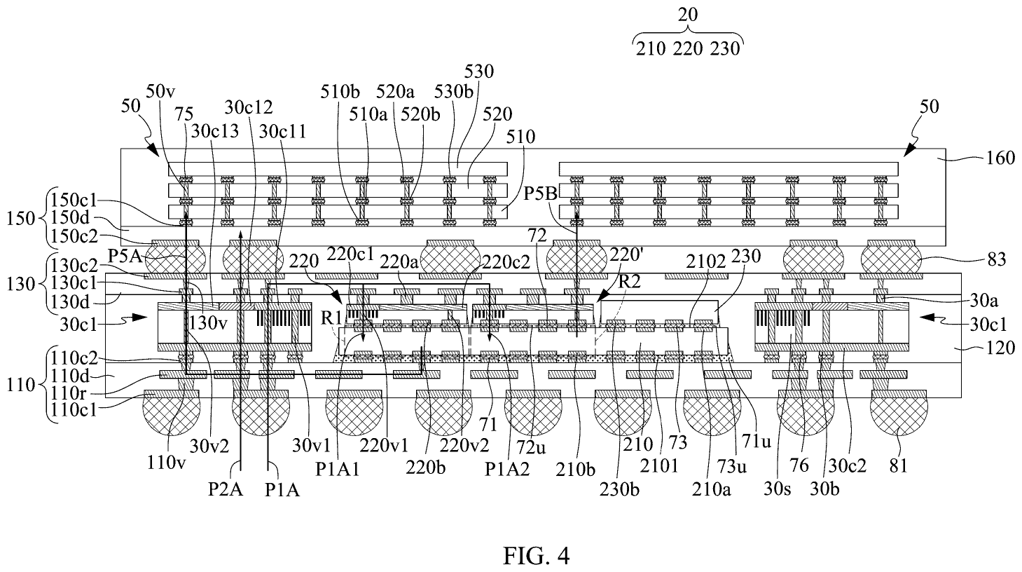

FIG. 4 is a cross-section of a package structure 4 in accordance with some arrangements of the present disclosure. The package structure 4 is similar to the package structure 1 in FIG. 1, and the differences therebetween are described as follows.

In some arrangements, the processing element 210 includes portions R1 and R2 configured to perform different functions. For example, the portions R1 and R2 may be sensitive to noises of different frequencies.

In some arrangements, the processing module 20 includes decoupling elements 220 and 220′ over the processing element 210. In some arrangements, the decoupling elements 220 and 220′ are configured to decouple a first noise and a second noise of different frequencies, respectively. In some arrangements, the power regulating module 30 is configured to transmit a power signal to the processing element 210. In some arrangements, the decoupling element 220 is over the portion R1 and configured to decouple the first noise from the power signal and transmit the power signal to the portion R1. In some arrangements, the decoupling element 220′ is over the portion R2 and configured to decouple the second noise from the power signal and transmit the power signal to the portion R2. In some arrangements, the path P1A is configured to transmit the power signal from the power regulating module 30. In some arrangements, the path P1A may split into paths P1A1 and P1A2. The path P1A1 may be configured to transmit the power signal to the decoupling element 220, the first noise may be decoupled from the power signal by the decoupling element 220, and then the power signal is transmitted to the portion R1 of the processing element 210. The path P1A2 may be configured to transmit the power signal to the decoupling element 220′, the second noise may be decoupled from the power signal by the decoupling element 220′, and then the power signal is transmitted to the portion R2 of the processing element 210. In some arrangements, the portion R1 is more sensitive to the first noise, and the second portion R2 is more sensitive to the second noise.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a processing module comprising a processing element having a first side configured to receive power;
a storage module; and
a power regulating module disposed adjacent to the processing module, wherein the power regulating module comprises:
a first portion configured to decouple a first noise from a first power signal and transmit the first power signal to the first side of the processing element; and
a second portion configured to transmit a second power signal to the storage module.

2. The package structure as claimed in claim 1, wherein the first portion is closer to the processing element than the second portion is.

3. The package structure as claimed in claim 1, wherein the power regulating module further comprises a third portion configured to provide electrical communication between the processing element and the storage module.

4. The package structure as claimed in claim 3, wherein the first portion is closer to the processing element than the third portion is.

5. The package structure as claimed in claim 3, wherein the third portion is configured to transmit an electrical signal from the processing element to control access to the storage module.

6. The package structure as claimed in claim 3, wherein the power regulating module comprises a first conductive via configured to transmit the first power signal and a second conductive via electrically connected to the third portion, and a width of the second conductive via is less than a width of the first conductive via.

7. The package structure as claimed in claim 1, wherein the second portion is configured to decouple a second noise from the second power signal and transmit the second power signal to the storage module.

8. The package structure as claimed in claim 1, wherein the power regulating module comprises a plurality of capacitor structures, and a distribution density of the capacitor structures in a first region closer to the processing element is greater than a distribution density of the capacitor structures in a second region distal from the processing element.

9. The package structure as claimed in claim 1, wherein the power regulating module is stacked between the storage module and the processing module.

10. The package structure as claimed in claim 9, wherein the processing module further comprises:
a decoupling element configured to decouple a second noise from the first power signal, wherein the first noise and the second noise have different frequencies.

11. A package structure, comprising:
a processing module comprising:
a processing element having a first side; and
a decoupling element configured to decouple a first noise from a first power signal and transmit the first power signal to the first side of the processing element;
a storage module over the processing module; and
a power regulating module disposed adjacent to the processing module and configured to transmit a first signal to the storage module.

12. The package structure as claimed in claim 11, wherein the power regulating module comprises a conductive via configured to transmit the first signal to the storage module.

13. The package structure as claimed in claim 11, wherein the decoupling element comprises a first portion configured to decouple the first noise from the first power signal and a second portion configured to provide electrical communication between the processing element and the storage module.

14. The package structure as claimed in claim 13, wherein the decoupling element comprises a first conductive via connected to the first portion and configured to transmit the first power signal.

15. The package structure as claimed in claim 14, wherein the decoupling element comprises a second conductive via connected to the second portion and configured to transmit an electrical signal from the processing element to control access to the storage module.

16. The package structure as claimed in claim 15, wherein a width of the second conductive via is less than a width of the first conductive via.

17. The package structure as claimed in claim 11, further comprising an encapsulant encapsulating the processing module and the power regulating module.

18. A package structure, comprising:
a processing module comprising a processing element having a first side configured to receive power; and
a power regulating module disposed adjacent to the processing module, wherein the power regulating module is configured to transmit a power signal, and a power path is configured to transmit the power signal by vertically passing the power regulating module and horizontally extending toward the first side of the processing element.

19. The package structure as claimed in claim 18, wherein the processing module comprises a first decoupling element and a second decoupling element over the processing element and configured to decouple a first noise and a second noise of different frequencies, respectively.

20. The package structure as claimed in claim 19, wherein the processing element comprising a first portion and a second portion configured to perform different functions, the first decoupling element is over the first portion and configured to decouple the first noise from the power signal and transmit the power signal to the first portion, and the second decoupling element is over the second portion and configured to decouple the second noise from the power signal and transmit the power signal to the second portion.
